(19) United States
(12) Patent Application Publication
(10) Pub. No.: US 2010/0032015 A1
(43) Pub. Date: Feb. 11, 2010

(54) System and method for generating power from solar radiation

(76) Inventor: Tariq I. Bokhary, Dammam (SA)

Correspondence Address: LITMAN LAW OFFICES, LTD., POST OFFICE BOX 15035, CRYSTAL CITY STATION, ARLINGTON, VA, 22215-0035, US

(21) Appl. No.: 12/222,374

(22) Filed: Aug. 7, 2008

(51) Int. Cl. H01L 31/02

(52) U.S. Cl. 136/259

(57) ABSTRACT

The system for generating power from solar radiation is an energy production system that utilizes ultraviolet radiation, such as that generated by the sun, to produce ozone from diatomic oxygen gas. The system includes a housing having a lower wall, an upper wall and at least one sidewall, with the housing defining an open interior region. The upper wall is at least partially transparent to ultraviolet radiation, and inlet and outlet ports are formed through the housing. The ultraviolet radiation converts the oxygen gas into ozone gas, and the ozone gas diffuses into an electrolytic solution, where the ozone gas is broken into ionized monatomic oxygen and ionized diatomic oxygen gas. The ionized monatomic gas bonds to a cathode and ions from the electrolytic solution bond with an anode. Leads are secured to the anode and cathode for drawing usable electricity from the system.

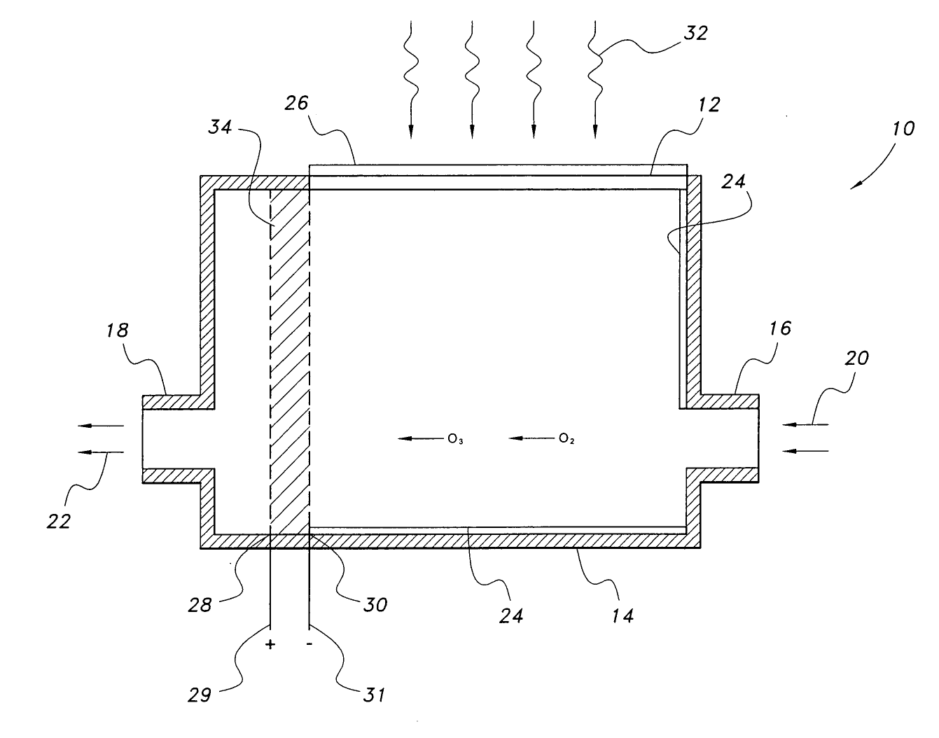

### BACKGROUND OF THE INVENTION

1. Field of the Invention

The present invention relates to a systems and methods for generating power from solar radiation, particularly electrical power, and to systems for generating electrical power as a byproduct of producing ozone from ultraviolet radiation.

2. Description of the Related Art

In recent years, developing alongside a global rise in environmental consciousness and the problem of the greenhouse effect brought by carbon dioxide pollution, the application of renewable energy has become an important issue. Both solar energy and fuel cells are of particular interest for the production of “clean” electrical power. Solar energy, however, is limited due to the low-conversion rates from solar energy to electrical energy via conventional solar cells.

Fuel cells are dependent on an electrochemical reaction to generate electrical energy without combustion. Typical fuel cells use hydrogen and oxygen to produce an electron flow for generating an electrical current, with waste products being either non-existent or minimal. Present fuel cells, however, are either extremely inefficient, or the energy required to produce the fuel (such as in hydrogen fuel cells) makes the production of such fuel cells non-viable. The energy to charge the cell further must come from conventional sources; i.e., petrochemical reactions.

It would be desirable to provide an electrochemical cell having no dangerous environmental byproducts, which is charged and powered through a clean and readily available source of energy, such as solar energy. Thus, a system and method for generating power from solar radiation solving the aforementioned problems is desired.

### SUMMARY OF THE INVENTION

The system for generating power from solar radiation is an energy production system that utilizes ultraviolet radiation, such as that generated by the sun, to produce ozone from diatomic oxygen gas. The ozone, through an electrochemical process, is then used to produce usable electricity. The system includes a housing having a lower wall, an upper wall and at least one sidewall, with the housing defining an open interior region. The upper wall is at least partially transparent to ultraviolet radiation, and inlet and outlet ports are formed through the housing.

A pair of porous screens, each having a plurality of apertures formed therethrough, are secured within the open interior region of the housing, preferably adjacent the outlet port, which is preferably formed through the at least one side wall, with the apertures being sized to allow for the diffusion of gas through each of the porous screens but not allowing liquid to pass therethrough. One of the pair of porous screens forms an anode and the other of the porous screens forms a cathode. The pair of porous screens are positioned adjacent one another and extend from the lower wall to the upper wall.

A volume of an electrolytic solution is held between the pair of porous screens, the upper wall and the lower wall. The electrolytic solution may be held as a pure liquid or may be absorbed within an absorptive layer. The solution is preferably potassium hydroxide dissolved in water, to form an ionic solution of positive potassium ions and negative hydroxide ions.

A pump or other system for injecting oxygen gas into the open interior region through the inlet port is provided, such that the oxygen gas is received within the open interior region and is exposed to the ultraviolet radiation projected through the transparent upper wall. The ultraviolet radiation converts the oxygen gas into ozone gas, and the ozone gas diffuses into the electrolytic solution (under the power of the pump), where the ozone gas is broken into ionized monatomic oxygen and ionized diatomic oxygen gas. The ionized monatomic gas bonds to the cathode to produce a positive electrical charge thereon, and ions from the electrolytic solution bond with the anode to produce a negative electrical charge thereon. Leads are secured to the anode and cathode for drawing usable electricity from the system. Waste oxygen gas is then diffused out of the solution and exits the housing through the outlet port.

These and other features of the present invention will become readily apparent upon further review of the following specification and drawings.

### BRIEF DESCRIPTION OF THE DRAWINGS

The sole FIGURE is a side view in section of a system for generating power from solar radiation according to the present invention.

Similar reference characters denote corresponding features consistently throughout the attached drawings.

### DETAILED DESCRIPTION OF THE PREFERRED EMBODIMENT

The present invention is directed towards a system for generating power from solar radiation 10. The system 10 is an energy production system that utilizes ultraviolet radiation (shown in the FIGURE as 32), such as that generated by the sun, to produce ozone (O₃) from diatomic oxygen gas (O₂). The ozone, through an electrochemical process (to be described in detail below), is then used to produce usable electricity. The system 10 includes a housing 14 having a lower wall, an upper wall and at least one sidewall, with the housing 14 defining an open interior region. The upper wall is at least partially transparent to ultraviolet radiation 32, and inlet and outlet ports 16, 18, respectively, are formed through the housing 14. The dimensions and contouring of the housing 14 are depending upon the volume of oxygen gas to be converted into ozone (and the power output resulting therefrom).

In the FIGURE, the upper wall is shown as including a lens 12. The upper wall may be fully transparent, and is either covered by lens 12, or lens 12 may form part or all of the upper wall. Lens 12 may be a Fresnel lens or any other focusing, refractive lens. A filter layer 26 is further preferably provided, for allowing only ultraviolet frequencies to enter the open interior region of the housing 14. Further, the inner surface of the housing 14 is preferably coated with an optically reflective layer 24 for concentrating the ultraviolet radiation on the oxygen injected therein.

A pair of porous screens 28, 30, respectively, each having a plurality of apertures formed therethrough, are secured within the open interior region of the housing 14, preferably adjacent the outlet port 18, which is preferably formed through the at least one side wall (opposite the inlet port 16), with the apertures being sized to allow for the diffusion of gas through each of the porous screens but not allowing liquid to pass therethrough. One of the pair of porous screens forms an anode 30 and the other of the porous screens forms a cathode 28. The porous screens 28, 30 are preferably metallic and are formed from a material, which is non-reactive with the electrolytic solution to be described below. The pair of porous screens 28, 30 are positioned adjacent one another, as shown, and extend from the lower wall to the upper wall.

A volume of an electrolytic solution is held between the pair of porous screens 28, 30, the upper wall and the lower wall. The electrolytic solution may be held as a pure liquid or may be absorbed within an absorptive layer. The solution is preferably potassium hydroxide dissolved in water, to form an ionic solution of positive potassium ions and negative hydroxide ions.

A pump or other system for injecting oxygen gas into the open interior region through the inlet port 20 is provided (the input oxygen is shown as 20 in the FIGURE), such that the oxygen gas is received within the open interior region and is exposed to the ultraviolet radiation 32 projected through the transparent upper wall. The oxygen gas may be input as pure oxygen gas, or may be input in the form of ambient air, with the other gases from the air exiting through outlet 18 (output gas is shown as 22 in the FIGURE).

The ultraviolet radiation 32 converts the oxygen gas into ozone gas, and the ozone gas diffuses into the electrolytic solution (under the power of the pump), where the ozone gas is broken into ionized monatomic oxygen and ionized diatomic oxygen gas. The application of the ultraviolet radiation, in addition to creating stable ozone, also produces ionized monatomic oxygen, prior to insertion within the electrolytic solution. The ionized monatomic gas from both the breakdown of the ozone and from the ionizing application of ultraviolet radiation, bonds to the cathode 28 to produce a positive electrical charge thereon, and ions from the electrolytic solution bond with the anode 30 to produce a negative electrical charge thereon. Leads 29, 31 are secured to the cathode and anode 29, 31, respectively, for drawing usable electricity from the system. Waste oxygen gas is then diffused out of the solution and exits the housing 14 through the outlet port 18. Such electrochemical cells utilizing ozone are known the art, one example of which is shown in the U.S. Provisional Patent Application titled “Method of Utilizing Ozone to Generate Electrical Energy”, to Bruce A. Perreault, and published by the inventor. This reference is herein incorporated by reference.

It is to be understood that the present invention is not limited to the embodiment described above, but encompasses any and all embodiments within the scope of the following claims.

I claim:

1. A system for generating power from solar radiation comprising:
a housing having a lower wall, an upper wall and at least one side wall, the housing defining an open interior region, the upper wall being at least partially transparent to ultraviolet radiation, inlet and outlet ports being formed through the housing;
a pair of porous screens each having a plurality of apertures formed therethrough, the apertures being sized to allow for the diffusion of gas through each of said porous screens but not allowing liquid to pass therethrough, one of said pair of porous screens forming an anode, the other of said pair of porous screens forming a cathode, said pair of porous screens being secured within the open interior region of said housing, said pair of porous screens being positioned adjacent one another and extending from the lower wall to the upper wall;
a volume of an electrolytic solution held between said pair of porous screens, the upper wall and the lower wall; and
means for injecting oxygen gas into the open interior region through the inlet port, whereby the oxygen gas is received within the open interior region and exposed to the ultraviolet radiation through the upper wall, the ultraviolet radiation converting the oxygen gas into ozone gas, the ozone gas diffusing into the electrolytic solution where the ozone gas is broken into ionized monatomic oxygen and ionized diatomic oxygen gas, the ionized monatomic gas bonding to the cathode to produce a positive electrical charge thereon, ions from the electrolytic solution bonding with the anode to produce a negative electrical charge thereon.

2. The system for generating power from solar radiation as recited in claim 1, further comprising a lens being positioned adjacent the upper wall of the housing to focus the ultraviolet radiation within the open interior region thereof.

3. The system for generating power from solar radiation as recited in claim 2, further comprising an ultraviolet filter positioned adjacent the lens for allowing only ultraviolet radiation to enter the open interior region.

4. The system for generating power from solar radiation as recited in claim 1, further comprising an optically reflective layer coating an interior surface of the housing.

5. The system for generating power from solar radiation as recited in claim 1, wherein the electrolytic solution is a potassium hydroxide solution.

6. The system for generating power from solar radiation as recited in claim 1, wherein said inlet and outlet ports are formed through the at least one side wall.

7. The system for generating power from solar radiation as recited in claim 1, further comprising a pair of electrical leads secured to the anode and the cathode and extending outwardly from said housing.

8. A method for generating power from solar radiation, comprising the steps of:
exposing diatomic oxygen gas to ultraviolet radiation to convert the oxygen gas into ozone gas;
diffusing the ozone gas into an electrolytic solution trapped between an anode and a cathode;
the ozone gas forming ionized monatomic oxygen and ionized diatomic oxygen gas, the ionized monatomic gas bonding to the cathode to produce a positive electrical charge thereon; and
ions from the electrolytic solution bonding with the anode to produce a negative electrical charge thereon.

9. The method for generating power from solar radiation as recited in claim 8, further comprising the step of focusing the ultraviolet radiation on the diatomic oxygen gas through refraction.

10. The method for generating power from solar radiation as recited in claim 9, further comprising the step of concentrating the ultraviolet radiation on the diatomic oxygen gas through reflection.
